(19) United States
(12) Patent Application Publication
(10) Pub. No.: US 2024/0027528 A1
(43) Pub. Date: Jan. 25, 2024

(54) WIRELESS BATTERY MANAGEMENT SYSTEM SERVICING

(71) Applicant: Analog Devices International Unlimited Company, Limerick (IE)

(72) Inventors: Narsimh Dilip KAMATH, Bangalore (IN); Douglas Lewis, Durham, NC (US); Andre Wolokita, Melbourne (AU)

(21) Appl. No.: 18/183,872

(22) Filed: Mar. 14, 2023

(30) Foreign Application Priority Data
Mar. 16, 2022 (IN) 202241014168

(51) Int. Cl. G01R 31/36; G08C 17/02; G01R 31/371

(52) U.S. Cl. CPC G01R 31/3648; G08C 17/02; G01R 31/371

(57) ABSTRACT

A battery module includes a plurality of battery cells and a battery monitoring system configured to monitor one or more parameters of the plurality of battery cells. The battery module includes a processor configured to execute a battery monitoring script to generate a battery information payload defined by a battery information payload format. The battery module includes a radio configured to receive a container file including metadata defining the battery information payload format and the battery monitoring script; transmit the metadata to a service device; and transmit the battery information payload to the service device. A battery pack includes one or more battery modules and a wireless battery management system controller configured to: receive the battery information payload from each of the plurality of the battery modules; and provide aggregated battery information to a battery management controller of a host.

### CROSS-REFERENCE TO RELATED APPLICATIONS

This application claims priority to Indian Provisional Application No. 202241014168 titled “WIRELESS BATTERY MANAGEMENT SYSTEM SERVICING” and filed Mar. 16, 2022, which is assigned to the assignee hereof and incorporated herein by reference.

### TECHNICAL FIELD

This disclosure is related to wireless battery management systems, and more particularly to servicing wireless battery management systems.

### INTRODUCTION

An electric vehicle includes multiple battery cells to store power. The cells may be organized into battery packs. The battery packs may be equipped with a board or integrated circuit (IC) for monitoring and controlling the cells. For example, the IC may monitor a voltage and temperature of each cell.

A battery management system (BMS) may collect and aggregate information from multiple battery packs. The BMS may be an interface between the battery system and the electric vehicle. A conventional BMS may use a wiring harness to connect each battery pack to the BMS. Such wiring harnesses may involve complex wiring schematics, which may be different for each model of electric vehicle.

A wireless battery management system (wBMS) has been proposed to simplify wiring schematics in electric vehicles. In a wBMS, each battery pack may communicate wirelessly with the BMS. While a wBMS may simplify the hardware wiring in an electric vehicle, the wBMS also presents unique technical challenges.

### SUMMARY

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its sole purpose is to present some concepts of one or more aspects in a simplified form as a prelude to the more detailed description that is presented later.

In some aspects, the techniques described herein relate to a battery module, including: a plurality of battery cells; a battery monitoring system configured to monitor one or more parameters of the plurality of battery cells; a processor configured to execute a battery monitoring script to generate a battery information payload defined by a battery information payload format; and a radio configured to: receive a container file including metadata defining the battery information payload format and the battery monitoring script; transmit the metadata to a service device; and transmit the battery information payload to the service device.

In some aspects, the techniques described herein relate to a battery module, wherein the radio includes a non-volatile memory configured to store the container file and the processor includes a volatile memory and is configured to load the battery monitoring script upon initialization.

In some aspects, the techniques described herein relate to a battery module, wherein the radio is configured to transmit the metadata to a wireless battery management system that is configured to provide the metadata to the service device.

In some aspects, the techniques described herein relate to a battery module, wherein the radio is configured to transmit the metadata directly to the service device in response to a request from the service device.

In some aspects, the techniques described herein relate to a battery module, wherein the processor is configured to execute a data processing engine (DPE) to process data received from the battery monitoring system, wherein the battery monitoring script includes: a set of battery monitor command source files used to write commands to the battery monitoring system and read results from the battery monitoring system via a serial peripheral interface (SPI); and a set of DPE source files that provide commands to process the data received from the battery monitoring system to generate the battery information payload according to the battery information payload format.

In some aspects, the techniques described herein relate to a battery module, wherein the processor is configured to execute a scheduler to generate a plurality of packets according to the battery information payload format, wherein the battery monitoring script includes: an initialization schedule that provides a set of pointers to lists of BMS and DPE commands to be run at initialization; and an active mode schedule that provides the processor with pointers to lists of battery management system and DPE commands to be run within a timed subloop.

In some aspects, the techniques described herein relate to a battery module, wherein the battery monitoring script includes a battery monitor command configuration file containing information about a configuration of the battery module.

In some aspects, the techniques described herein relate to a battery module, wherein the battery monitoring script includes cell balancing command fragments that can be instantiated at run time via parameter data from a cell balancing message received via the radio.

In some aspects, the techniques described herein relate to a battery pack including: a plurality of battery modules; and a wireless battery management system controller configured to: receive the battery information payload from each of the plurality of the battery modules; and provide aggregated battery information to a battery management controller of a host.

In some aspects, the techniques described herein relate to an electric vehicle including the battery pack.

In some aspects, the techniques described herein relate to a method of battery management, including: obtaining, at a processor of a battery module, a container file including metadata defining a battery information payload format and code for generating the battery information payload; executing the code to generate a battery information payload according to the battery information payload format; exporting the metadata of the container file, via a radio, to a service device; and transmitting the battery information payload to the service device via the radio.

In some aspects, the techniques described herein relate to a method, wherein obtaining the container file includes: receiving, at the radio, the container file from a wireless battery management system; and loading the container file from a non-volatile memory of the radio to a volatile memory of the processor.

In some aspects, the techniques described herein relate to a method, wherein exporting the metadata includes exporting the metadata via the wireless battery management system.

In some aspects, the techniques described herein relate to a method, wherein exporting the metadata includes transmitting the metadata directly to the service device.

In some aspects, the techniques described herein relate to a method, wherein the code to generate the battery information payload according to the battery information payload format includes one or more of: a set of battery monitor commands source files used to write commands and read results to a battery monitoring system via a serial peripheral interface (SPI) from the processor; a set of data processing engine (DPE) source files that provide commands to a DPE running on the processor used to process data received from the battery monitoring system; an active mode schedule that provides the processor with pointers to lists of battery management system (BMS) and DPE commands to be run within a timed subloop; an initialization schedule that provides a set of pointers to lists of BMS and DPE commands to be run at initialization; a battery monitor command configuration file containing information about a configuration of the battery module; or cell balancing command fragments that can be instantiated at run time via parameter data from a cell balancing message received via the radio.

In some aspects, the techniques described herein relate to a method of battery diagnostics, including: obtaining at least a portion of a container file including metadata defining a battery information payload format and a script for generating a battery information payload from a battery module, via a radio; receiving, from the battery module via the radio, a battery information payload; and parsing the battery information payload according to the battery information payload format to determine measurement information or fault information.

In some aspects, the techniques described herein relate to a method, wherein obtaining the container file includes: initializing the battery module; and reading a container file from a non-volatile memory of a radio of the battery module.

In some aspects, the techniques described herein relate to a method, wherein obtaining the container file includes requesting the container file from a wireless battery management system; and receiving the container file from the battery module via the wireless battery management system.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

To provide a more complete understanding of the present disclosure and features and advantages thereof, reference may be made to the following description, taken in conjunction with the accompanying figures, wherein like reference numerals represent like parts, in which:

FIG. 1 is a diagram of a battery system within a vehicle;

FIG. 2 is a data flow diagram showing an example of configuration and operation of a battery module;

FIG. 3 is a data flow diagram showing an example of servicing of a battery module;

FIG. 4 is a diagram of an example container file including metadata and a battery monitoring script;

FIG. 5 is a diagram of an example battery information packet including a payload;

FIG. 6 is an example schema for metadata describing a structure of a battery information packet;

FIG. 7 is a message diagram showing example messages to configure a battery module;

FIG. 8 is a message diagram showing example messages to service a battery module;

FIG. 9 is a flowchart of an example method performed by a battery module;

FIG. 10 is a flowchart of an example method performed by a service device.

### DETAILED DESCRIPTION

A wireless battery management system (wBMS) or the battery modules may communicate with a service device to identify and isolate a problem or to detect potential issues with the battery system. A service device may communicate with an electronic component of a vehicle by receiving messages from the component either as part of a diagnostic function or by monitoring messages during normal operation. For the service device to be able to parse or understand the messages, the service device needs to know a format of the messages. Conventionally, a service device either stores information regarding the format for various messages or accesses a database including such information. The state of the art in terms of servicing of wBMS today is to maintain a server with a list of all the possible data structures in use across hardware and software versions employed in the field. The service equipment then compares the version detected versus the server list in order to retrieve the appropriate data structure to use. The same database can also be hard coded in the service equipment local memory.

A wBMS may provide a capability to dynamically update operation of the battery modules at either a firmware or script level. For example, a BMS script may be loaded onto a processor of the battery module to schedule different tests or to process measurements. While the flexibility of dynamic configuration of the battery modules may provide a performance improvement of the wBMS, the possibility of dynamic configuration poses a technical problem for service devices. Although the wBMS may also be updated to receive messages based on the dynamic configuration of the battery module, a service device may not have access to the dynamic configuration. Additionally, a service device may interact with different battery modules in the same battery system or in different battery systems. For instance, battery modules may use different monitoring circuits, different configurations of cells, or have different requirements, all of which may drive a large number of different packet formats. Managing the different formats of packets being parsed by the service device poses a technical problem. For instance, a database may become quite large due to configuration options and may not fit on internal memory of the service device, or a database may not be up to date.

In an aspect, the present disclosure provides systems and methods for a battery module to provide information regarding a structure of a battery information payload to a service device. The service device may receive the information when accessing the battery module, and may then parse information packets transmitted by the battery module for diagnostics and/or display in human readable form. For example, metadata including the information regarding the structure of the battery information payload may be included in a container file that includes a script executed by the processor of the battery module. The battery module may store the container file including the metadata, for example, in a non-volatile memory of a radio. The battery module may transmit the container file (or just the metadata) to a service device. Accordingly, the service device may receive the metadata including the information regarding the structure of the battery information payload from the battery module. This ensures that the service device has access to the correct formatting information.

In some implementations, the present disclosure describes a method to store information related to the data structure on the battery modules, and thereafter, providing a software application programming interface (API) to enable service equipment to retrieve said information on-demand. The API may allow a configuration provider (e.g., a battery system manufacturer) to load the container file to the battery module via the wBMS. The API may allow a service device to request at least the metadata portion of the container file via the wBMS or directly from the battery module. Accordingly, the API may allow a service device to read the metadata defining the payload structure on-demand.

In an aspect, the present disclosure may provide one or more of the following technical benefits. The techniques disclosed herein eliminate the overhead associated with maintaining a database on a server or requiring additional local memory and complex logic on the service device itself. The techniques may simplify the servicing of battery packs that employ wireless battery management systems (wBMS). The techniques may facilitate dynamic configuration of battery modules and improve the ability to service dynamically configured battery modules. Additionally, the techniques disclosed herein may facilitate servicing multiple variants of battery modules.

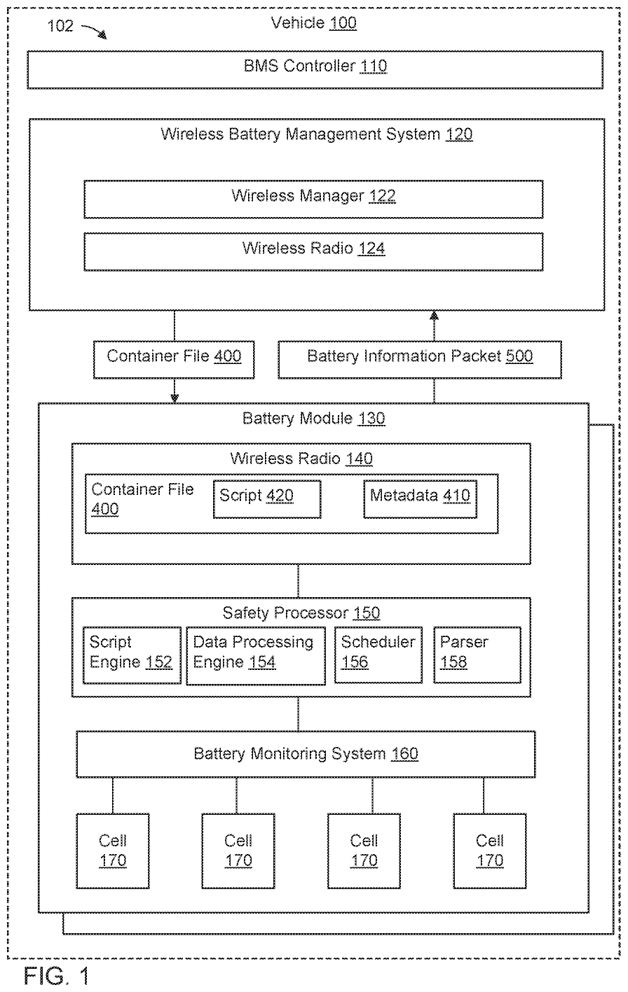

FIG. 1 is a diagram of a battery system 102 within a vehicle 100. The vehicle 100 may be an electric vehicle (EV) or a hybrid vehicle such as a plug-in hybrid electric vehicle. The vehicle 100 may be considered a host of the battery system 102. The battery system 102 may include a BMS controller 110, a wireless battery management system (wBMS) 120, and a plurality of battery modules 130.

The BMS controller 110 may be a component of the vehicle 100 configured to interface with the wBMS 120. For example, the BMS controller 110 may be an electronic control unit (ECU) of the vehicle 100. The BMS controller 110 may execute a BMS controller application, which may be referred to as a safety application. For instance, the BMS controller 110 may communicate with the wBMS 120 to receive information about the battery system such as state of charge, voltage, temperatures, and any faults that have occurred. The BMS controller 110 may also communicate with other vehicle components such as an inverter or charger.

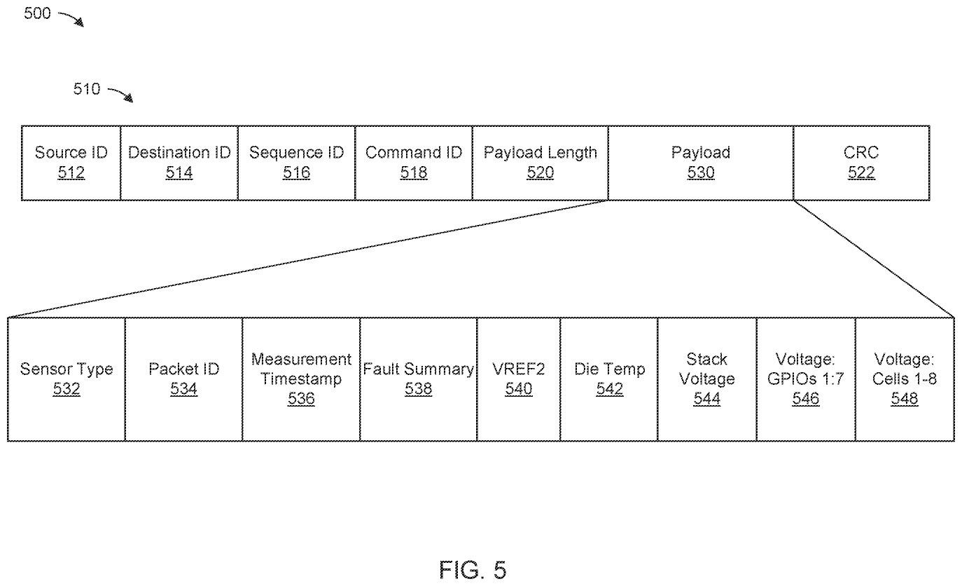

The wBMS 120 may be configured to interface between the battery modules 130 and the BMS controller 110. For example, the wBMS 120 may receive packets 500 (FIG. 5) including measurement messages and fault messages from the battery modules 130. The wBMS 120 may aggregate the messages from the individual battery modules to provide system level information to the BMS controller 110. The wBMS 120 may include a wireless manager 122 and a wireless radio 124. The wireless manager 122 may be configured to generate messages for transmission to the battery modules 130 and receive messages from the battery modules 130. The wireless manager 122 may include a radio protocol stack. The wireless radio 124 may include one or more radios configured to transmit radio-frequency (RF) signals to the battery modules 130. The wireless radio 124 may be referred to as a head radio and may control (e.g., schedule) the communications with the battery modules 130.

The battery module 130 may include a wireless radio 140, a safety processor 150, a battery monitoring system 160, and a plurality of cells 170. The cells 170 may be battery cells that store power. In some implementations, each battery module 130 may include between 3 and 24 individual cells 170.

The battery monitoring system 160 may be configured to monitor one or more parameters of the plurality of battery cells. For example, the battery monitoring system 160 may monitor voltage and temperature of each cell. The battery monitoring system 160 may provide the measurements to the safety processor 150. The battery monitoring system 160 may be referred to as a battery monitoring integrated circuit (BMIC).

The safety processor 150 may be a computer processor configured to execute computer code such as a script. In some implementations, the safety processor 150 is a separate processor connected to the wireless radio 140 and the battery monitoring system 160 via interfaces such as a serial peripheral interface (SPI). In other implementations, the safety processor may be a processor of the wireless radio 140. The safety processor 150 may be configured to perform various tasks with respect to managing the battery module 130. For example, the safety processor 150 may be configured to execute a battery monitoring script to generate a battery information payload defined by a battery information payload format. The safety processor may also receive commands (e.g., a cell balancing command) from the wBMS 120, and write commands to the battery monitoring system 160. The safety processor 150 may include a script engine 152, a data processing engine 154, a scheduler 156, and a parser. The script engine 152 may execute a script received from wBMS 120. The data processing engine 154 may perform data processing commands defined by the script to write commands to the battery monitoring system 160 and process data received from the battery monitoring system 160. In some implementations, the data processing engine may be a component of the script engine. The scheduler 156 may be configured to generate a plurality of packets according to a battery information payload format. For example, the scheduler 156 may operate according to an initialization schedule at initialization to potentially generate fault packs and operate according to an active mode schedule to generate measurement messages within a timed subloop. The parser 158 may be configured to parse various components of the script 420.

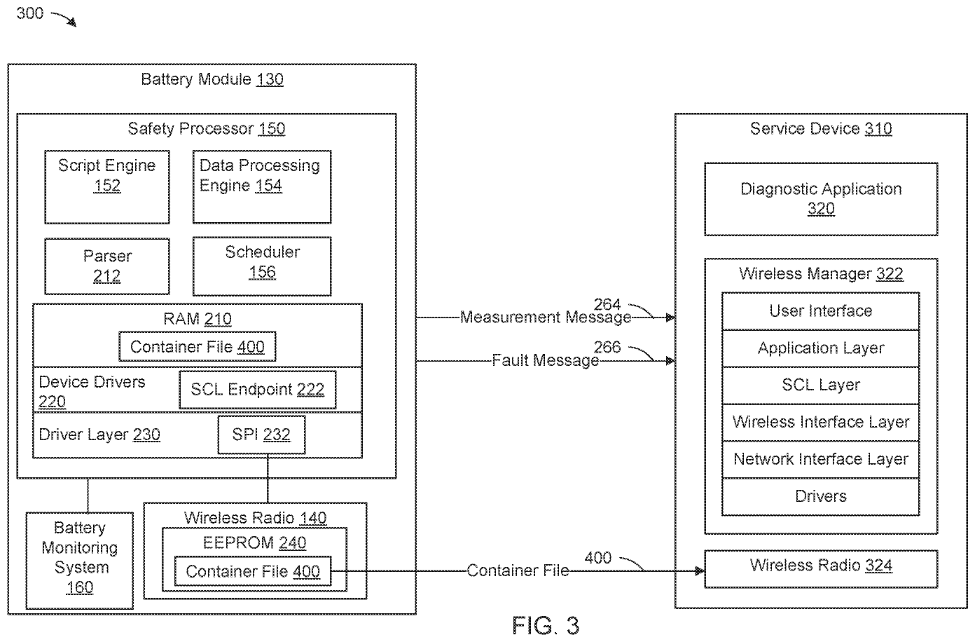

The wireless radio 140 may be configured to communicate with the wBMS 120 and/or a service device 310 (FIG. 3). The wireless radio 140 may be a radio similar to the wireless radio 124 configured to transmit and receive RF signals. The wireless radio 140 may be referred to a tail radio because the wireless radio 140 may be managed by the wireless radio 124. The wireless radio 140 is configured to receive a container file 400 from the wBMS 120. The container file 400 includes metadata 410 defining the battery information payload format and the battery monitoring script 420. The wireless radio 140 is configured to transmit at least the metadata 410 of the container file 400 to the service device 310. The wireless radio 140 is also configured to transmit packets including a battery information payload to either the wBMS 120 or the service device 310.

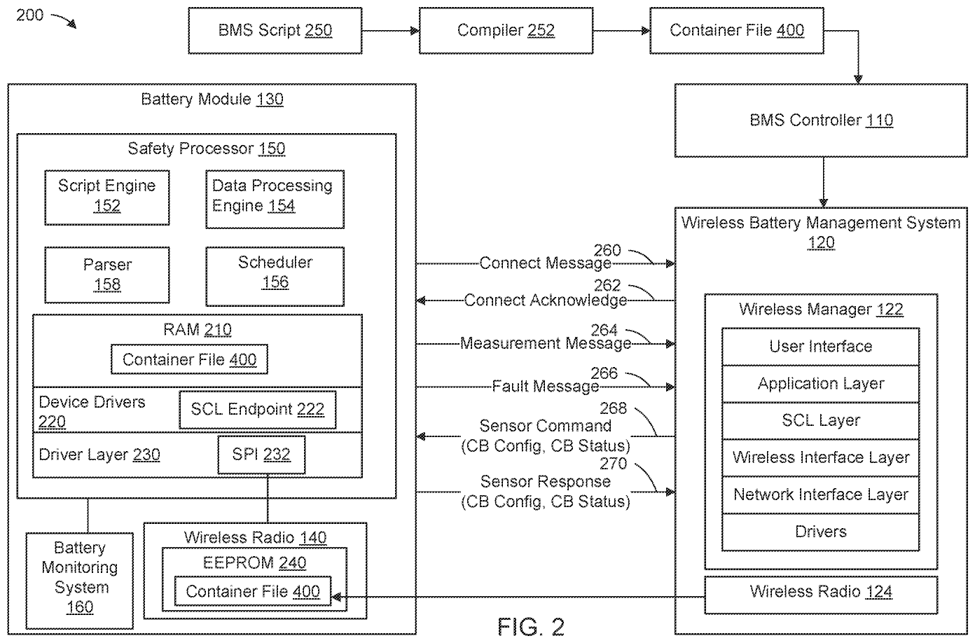

FIG. 2 is a data flow diagram 200 showing an example of configuration and operation of a battery module 130. The battery module 130 may be configured by a configuration provider (e.g., manufacturer) via the BMS controller 110 and wBMS 120 via the container file 400. The configuration provider may generate a BMS script 250 that includes code for execution by the safety processor 150 to make voltage and temperature measurements and perform fault diagnosis on the cells to which the battery monitoring system 160 of the battery module 130 is connected. The BMS script 250 may be written in a scripting language. The configuration provider may use a compiler 252 to compile the BMS script 250 and generate the container file 400. The container file 400 may be loaded to the battery module 130 through the BMS controller 110 and wBMS 120. For example, the BMS controller 110 may call an API function to load the container file 400.

In some implementations, the wireless radio 140 may include a non-volatile memory such as an electronically erasable programmable read only memory (EEPROM) 240 (e.g., flash memory). The EEPROM 240 may store the container file 400.

In an aspect, the safety processor 150 of the battery module 130 may include a volatile memory such as a random access memory (RAM) 210 that loads the container file 400 at initialization. The container file 400 may include the script 420 that controls operation of the script engine 152, data processing engine 154, scheduler 156, and parser 158 during operation. The RAM 210 may also store operating parameters for the script engine 152, data processing engine 154, scheduler 156, and parser 158 during operation.

In some implementations, the wireless manager 122 of the wBMS 120 may include a protocol stack. For example, the wireless manager may include a user interface, application layer, safety control layer (SCL), wireless interface layer, network interface layer, and drivers. The battery module 130 may similarly include a driver layer 230 and device drivers 220. For example, the wireless radio 140 may communicate with the safety processor via a serial peripheral interface (SPI) 232. The device drivers 220 may include a SCL endpoint 222.

During operation, the BMS controller 110 may communicate messages with the battery module 130 at the SCL layer. For example, the battery module 130 may transmit a connect message 260 to initiate a session with the wBMS 120. The wBMS 120 may respond with a connect acknowledge message 262. The battery module 130 may periodically transmit measurement message 264 including a battery information payload. The battery module 130 may also transmit a fault message 266, which may include a different battery information payload. In some implementations, the wBMS 120 may transmit a sensor command 268. For example, the sensor command 268 may be a cell balance configuration command that includes a new call balance configuration or a cell balancing status command that requests a current cell balancing configuration. The battery module 130 may push the cell balance configuration to the battery monitoring system 160, and transmit a sensor response message 270 including an updated cell balance configuration and status.

FIG. 3 is a data flow diagram 300 showing an example of servicing of a battery module 130 by a service device 310. The service device 310 may be an external device configured to communicate with the battery module 130. The service device 310 may be configured to diagnose an issue with the battery module 130 based on content of messages. Because the service device 310 is an external device (e.g., not part of vehicle 100), the service device 310 may not be configured with the same configuration information as the battery module 130. That is, the service device 310 may not receive the container file 400 from the configuration provider. The service device 310 may include a diagnostic application 320, a wireless manager 322, and a wireless radio 324.

In an aspect, the service device 310 may obtain at least the metadata 410 of the container file 400 from the battery module 130. In an aspect, the service device 310 may initialize the battery module 130. For example, the service device 310 may cause the battery module 130 to establish a wireless connection with the service device 310 instead of the wBMS 120. The service device 310 may read the container file 400, or at least the metadata 410, from the EEPROM 240 of the wireless radio 140. For example, the diagnostic application 320 of the service device 310 may call an API function to read the metadata 410. The wireless radio 140 may be configured to read the metadata 410 from the EEPROM 240 and transmit the metadata 410 in response to the API call. In some implementations, the service device 310 does not need access to the script 420 to parse messages from the battery module 130, so the script 420 may not be transmitted to the service device 310.

The diagnostic application 320 may be configured to parse battery information payloads based on the metadata 410. For example, the diagnostic application 320 may extract measurements from a measurement message 264 or fault information from a fault message 266. For instance, the metadata 410 may define which bits of the messages correspond to specific information fields. The diagnostic application 320 may be configured to present the information in a human readable form such as a chart or graph. In some implementations, the diagnostic application may analyze the battery payload information, for example by comparing received measurements over time or comparing received measurements to expected measurements. In some implementations, the service device 310 may run a diagnostic program by sending sensor commands to the battery module 130, for example, to test different cell balancing configurations.

The wireless manager 322 may be similar to the wireless manager 122. For example, the wireless manager 322 may include a protocol stack for communicating with the battery module 130. Likewise, the wireless radio 324 may be similar to the wireless radio 124.

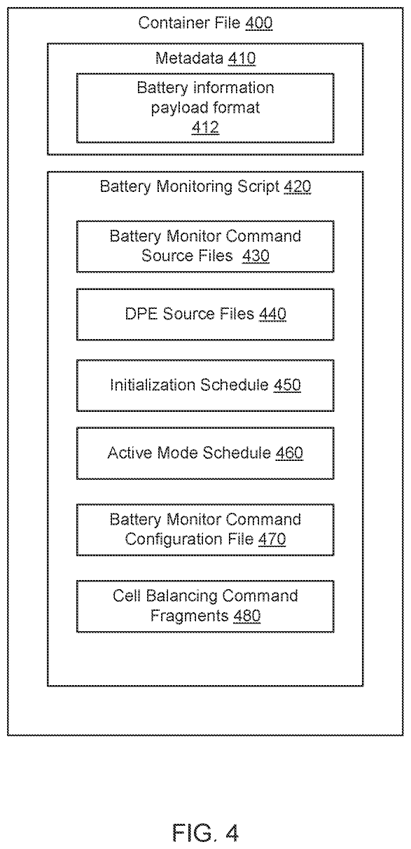

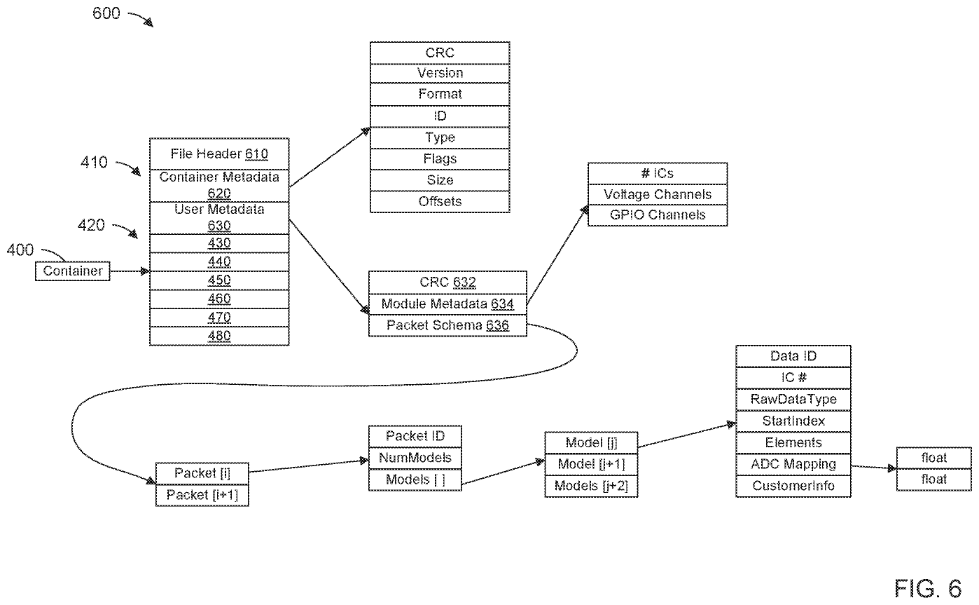

FIG. 4 is a diagram of an example container file 400 including metadata 410 and a battery monitoring script 420. The metadata 410 may include one or more battery information payload format 412. For example, the battery information payload format 412 may be a schema 600 (FIG. 6) defining content of a message. In some implementations, the metadata 410 may include a battery information payload format 412 for each type of message measurement message 264 and fault message 266).

The battery monitoring script 420 may include several components that control operation of the safety processor 150 and may affect the format of the payload data structure. For example, the battery monitoring script 420 may include battery monitor command source files 430, DPE source files 440, an initialization schedule 450, an active mode schedule 460, a battery monitor command configuration file 470, and cell balancing command fragments 480. The battery monitor command source files 430 may be used by the data processing engine 154 to write commands to the battery monitoring system 160 and read results from the battery monitoring system 160 via the SPI 232. The DPE source files 440 may provide commands to process the data received from the battery monitoring system 160 to generate the battery information payload according to the battery information payload format. The initialization schedule 450 may provide a set of pointers to lists of BMS and DPE commands to be run at initialization. The active mode schedule 460 may provide pointers to lists of battery management system and DPE commands to be run within a timed subloop. The battery monitor command configuration file 470 contains information about a configuration of the battery module. The cell balancing command fragments 480 can be instantiated at run time via parameter data from a cell balancing message (e.g., sensor command 268) received via the radio.

In some implementations, although the battery monitoring script 420 may control the safety processor 150 to generate the messages according to the battery information payload format 412, the battery monitoring script 420 does not need to be provided to the service device 310. For instance, the service device 310 may not be configured to execute or parse the battery monitoring script 420. Instead, the metadata 410 describes the battery information payload such that the service device 310 does not need the battery monitoring script 420.

FIG. 5 is a diagram of an example battery information packet 500 including a payload 530. The battery information packet 500 may include a header 510. In some implementations, the header 510 may be defined by the radio protocol and may use the same definition for each packet. For example, the header 510 may include a source identifier (ID) 512, a destination ID 514, a sequence ID 516, a command ID 518, a payload length 520, and a cyclic redundancy check (CRC) value 522. In some implementations, the CRC value 522 may be at the end of the packet 500, after the payload 530.

The payload 530 may be defined by the battery information payload format 412. In the illustrated example, the payload 530 may include a sensor type 532, packet ID 534, measurement timestamp 536, fault summary 538, reference voltage (VREF2) 540, die temperature 542, stack voltage 544, general purpose input output (GPIO) voltages 546, and cell voltages 548. The battery information payload format 412 indicates which information fields are present in the payload 530. The battery information payload format 412 may also define a length of each field. In some implementations, the battery information payload format 412 defines a number of each field (e.g., based on a number of cells). Accordingly, when the payload 530 is received at the diagnostic application 320 (e.g., as a stream of bits or bytes), the diagnostic application 320 may parse the payload 530 according to the battery information payload format 412.

FIG. 6 is an example schema 600 for a container file 400 including metadata 410 describing a structure of a battery information packet 500. The schema 600 may define the container file 400. In the schema 600, each element may include either a size of the element or a pointer to another element that further defines the element. The container file 400 may include a general file header 610 that defines the container file 400 and includes a CRC to check the integrity of the container file 400. The general file header may also include a version number, format, ID, type, flags, size, and offsets defining the start of each section. As discussed above, the container file includes metadata 410, which may include container metadata 620, and user metadata 630. The container file includes the script 420 including the battery monitor command source files 430, the DPE source files 440, the initialization schedule 450, the active mode schedule 460, the battery monitor command configuration file 470, and the cell balancing command fragments 480.

The user metadata 630 may describe the battery information payload format 412. In some implementations, the user metadata 630 includes a separate CRC 632 such that the integrity of the user metadata 630 may be independently checked if only the metadata 410 or the user metadata 630 is transmitted to the service device 310. The user metadata 630 may include module metadata 634 and packet schema 636. The packet schema 636 may define each type of message, for example, with a version, format, ID, type, flags, and size.

In an example, a packet may include a packet ID and a number of models. Each model may include a data ID, integrated circuit number (IC#), raw data type, start index, information as to elements of the model such as number of elements, analog-to-digital converter (ADC) mapping, and customer information. For instance, the ADC mapping may include floating point values defining thresholds. It should be understood that the schema 600 may be adapted to the particular format of packets that will be generated based on the battery management script 420.

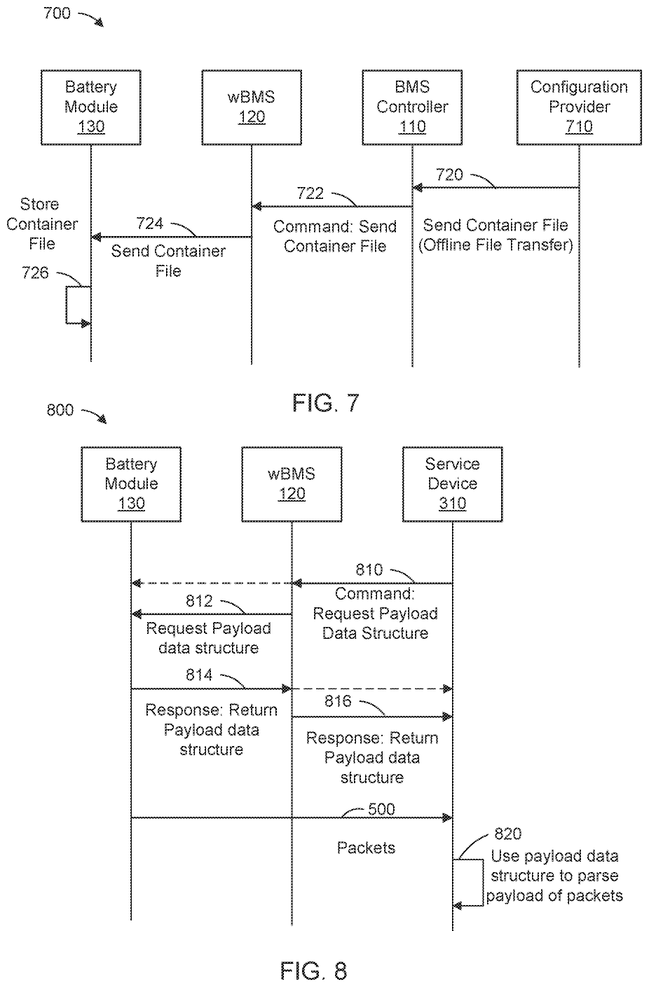

FIG. 7 is a message diagram 700 showing example messages to configure a battery module 130. For example, a configuration provider 710 may configure the battery module 130 with a container file 400. In a message 720, the configuration provider 710 may send the container file to the BMS controller 110. For example, the message 720 may be an offline file transfer (e.g., when the battery system is not in operation). The BMS controller 110 may send a command message 722 to the wBMS 120 to send the container file to a battery module 130. The wBMS 120 may transmit a message 724 sending the container file to the radio 140 of the battery module 130. The battery module 130 may store 726 the container file in the non-volatile memory of the radio 140.

FIG. 8 is a message diagram 800 showing example messages to service a battery module. The service device 310 may send a command 810 to the wBMS 120 to request the payload data structure (e.g., metadata 410). The wBMS 120 may forward a request 812 for the payload data structure. In some implementations, the service device 310 may transmit the command 810 directly to the battery module 130. The battery module 130 may respond to the request with a response 814 including the payload data structure. The wBMS 120 may forward a response 816 to the service device 310.

The battery module 130 may transmit packets 500 to the service device 310. At operation 820, the service device 310 may use the payload data structure to parse the payload 530 of the packets 500.

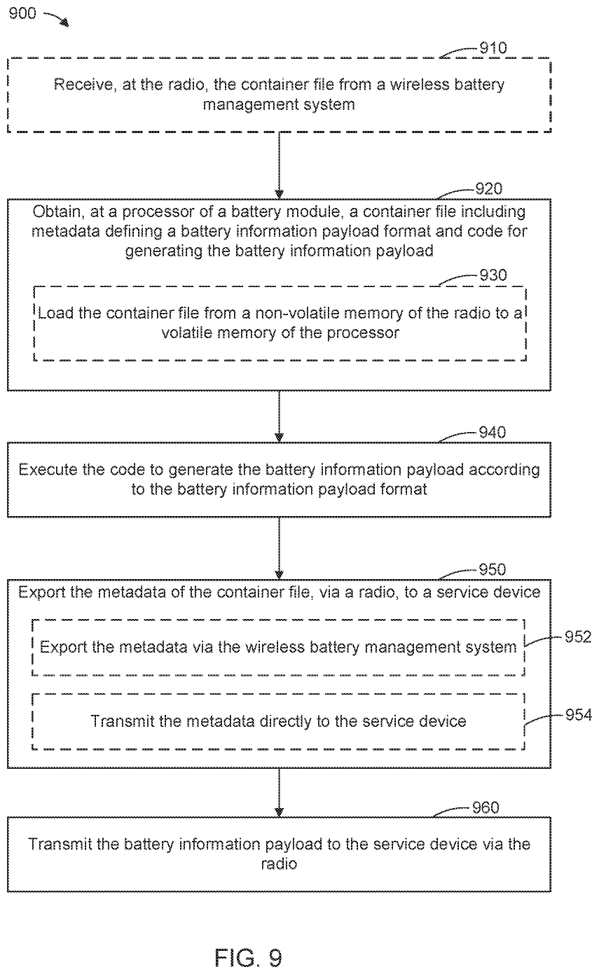

FIG. 9 is a flowchart of an example method 900 of battery management performed by a battery module 130. The method 900 may provide a battery information payload format and battery information payload to a service device. In some implementations, the method 900 may also include configuration of the battery module 130.

In block 910, the method 900 may optionally include receiving, at the radio, the container file from a wireless battery management system. For example, in some implementations, the wireless radio 140 may receive the container file 400 from the wBMS 120. In some implementations, the wireless radio 140 may store the container file 400 in the EEPROM 240.

In block 920, the method 900 includes obtaining, at a processor of the battery module, the container file including metadata defining a battery information payload format and code for generating the battery information payload. For instance, in some implementations, the safety processor 150 of the battery module 130 may obtain the container file 400 including metadata 410 defining a battery information payload format 412 and code (e.g., script 420) for generating the battery information payload 530. In some implementations, at block 930, the block 920 may optionally include loading the container file from a non-volatile memory (e.g., EEPROM 240) of the radio 140 to a volatile memory (e.g., RAM 210) of the safety processor 150.

In block 940, the method 900 includes executing the code to generate the battery information payload according to the battery information payload format. For example, in some implementations, the safety processor 150 may execute the script 420 to generate the battery information payload 530 according to the battery information payload format 412.

In block 950, the method 900 includes exporting the metadata of the container file, via the radio, to a service device. For instance, in some implementations, the radio 140 may export (e.g., transmit) the metadata 410 of the container file 400 to the service device 310. In some implementations, at sub-block 952, the radio 140 may export the metadata via the wBMS 120. In some implementations, at sub-block 954, the radio 140 may transmit the metadata directly to the service device 310. In some implementations, the radio 140 may export the entire container file 400 including the metadata 410.

In block 960, the method 900 includes transmitting the battery information payload to the service device via the radio. In some implementations, for example, the radio 140 may transmit the battery information payload 530 in a packet 500 to the service device 310.

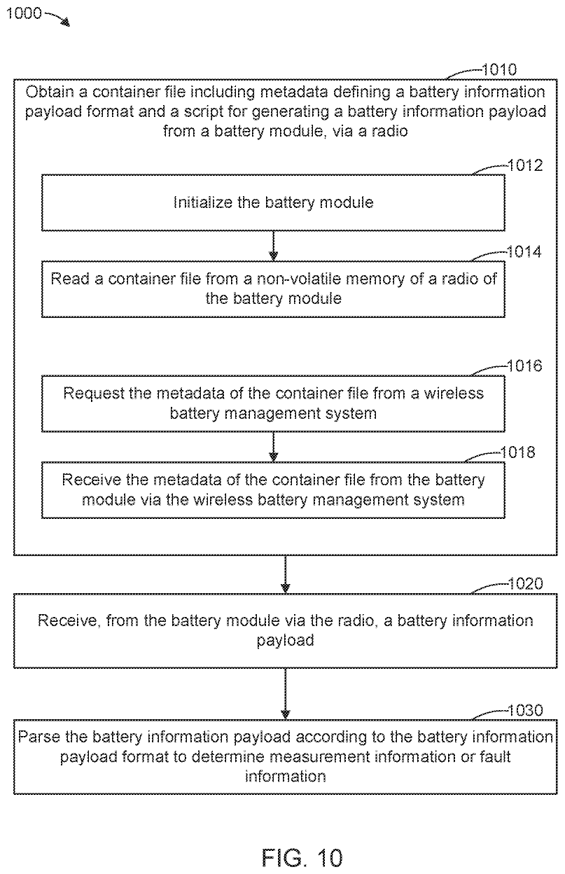

FIG. 10 is a flowchart of an example method 1000 performed by a service device 310. The method 1000 may be used to service (e.g., diagnose) the battery module 130.

In block 1010, the method 1000 includes obtaining at least a portion of a container file including metadata defining a battery information payload format and a script for generating a battery information payload from a battery module, via a radio. In some implementations, for example, the radio 324 may obtain at least the metadata 410 of the container file 400 including the metadata 410 defining the battery information payload format 412 and the script 420 for generating the battery information payload 530 from the battery module 130. For example, in some implementations, at sub-block 1012, the block 1010 may optionally include initializing the battery module 130. At sub-block 1014, the block 1010 may optionally include reading the container file from a non-volatile memory (e.g., EEPROM 240) of the radio 140 of the battery module 130. As another example, in some implementations, at sub-block 1016, the service device 310 may request the container file from a wBMS 120. At sub-block 1018, the block 1010 may optionally include receiving the metadata 410 of the container file 400 from the battery module 130 via the wBMS 120.

In block 1020, the method 1000 includes receiving, from the battery module via the radio, a battery information payload. In some implementations, for example, the radio 324 may receive the battery information payload 530 (e.g., in packet 500) from the battery module 130.

In block 1030, the method 1000 includes parsing the battery information payload according to the battery information payload format to determine measurement information or fault information. In some implementations, for example, the diagnostic application 320 may parse the battery information payload 530 according to the battery information payload format 412 to determine measurement information or fault information.

Numerous other aspects emerge from the foregoing detailed description and annexed drawings. Those aspects are represented by the following Clauses.

Clause 1. A battery module, comprising: a plurality of battery cells; a battery monitoring system configured to monitor one or more parameters of the plurality of battery cells; a processor configured to execute a battery monitoring script to generate a battery information payload defined by a battery information payload format; and a radio configured to: receive a container file including metadata defining the battery information payload format and the battery monitoring script; transmit the metadata to a service device; and transmit the battery information payload to the service device.

Clause 2. The battery module of clause 1, wherein the radio comprises a non-volatile memory configured to store the container file and the processor comprises a volatile memory and is configured to load the battery monitoring script upon initialization.

Clause 3. The battery module of clause 1 or 2, wherein the radio is configured to transmit the metadata to a wireless battery management system that is configured to provide the metadata to the service device.

Clause 4. The battery module of clause 1 or 2, wherein the radio is configured to transmit the metadata directly to the service device in response to a request from the service device.

Clause 5. The battery module of any of clauses 1-5, wherein the processor is configured to execute a data processing engine (DPE) to process data received from the battery monitoring system, wherein the battery monitoring script comprises: a set of battery monitor command source files used to write commands to the battery monitoring system and read results from the battery monitoring system via a serial peripheral interface (SPI); and a set of DPE source files that provide commands to process the data received from the battery monitoring system to generate the battery information payload according to the battery information payload format.

Clause 6. The battery module of clause 5, wherein the processor is configured to execute a scheduler to generate a plurality of packets according to the battery information payload format, wherein the battery monitoring script includes: an initialization schedule that provides a set of pointers to lists of BMS and DPE commands to be run at initialization; and an active mode schedule that provides the processor with pointers to lists of battery management system and DPE commands to be run within a timed subloop.

Clause 7. The battery module of any of clauses 1-6, wherein the battery monitoring script includes a battery monitor command configuration file containing information about a configuration of the battery module.

Clause 8. The battery module of any of clauses 1-7, wherein the battery monitoring script includes cell balancing command fragments that can be instantiated at run time via parameter data from a cell balancing message received via the radio.

Clause 9. A battery pack comprising: a plurality of the battery modules according to clause 1; and a wireless battery management system controller configured to: receive the battery information payload from each of the plurality of the battery modules; and provide aggregated battery information to a battery management controller of a host.

Clause 10. An electric vehicle comprising the battery pack of clause 9.

Clause 11. A method of battery management, comprising: obtaining, at a processor of a battery module, a container file including metadata defining a battery information payload format and code for generating the battery information payload; executing the code to generate a battery information payload according to the battery information payload format; exporting the metadata of the container file, via a radio, to a service device; and transmitting the battery information payload to the service device via the radio.

Clause 12. The method of clause 11, wherein obtaining the container file comprises: receiving, at the radio, the container file from a wireless battery management system; and loading the container file from a non-volatile memory of the radio to a volatile memory of the processor.

Clause 13. The method of clause 12, wherein exporting the metadata comprises exporting the metadata via the wireless battery management system.

Clause 14. The method of clause 11, wherein exporting the metadata comprises transmitting the metadata directly to the service device.

Clause 15. The method of any of clauses 11-14, wherein the code to generate the battery information payload according to the battery information payload format comprises one or more of: a set of batten monitor commands source files used to write commands and read results to a battery monitoring system via a serial peripheral interface (SPI) from the processor; a set of data processing engine (DPE) source files that provide commands to a DPE running on the processor used to process data received from the battery monitoring system.

Clause 16. The method of any of clauses 11-15, wherein the code to generate the battery information payload according to the battery information payload format comprises one or more of: an active mode schedule that provides the processor with pointers to lists of battery management system (BMS) and DPE commands to be run within a timed subloop; or an initialization schedule that provides a set of pointers to lists of BMS and DPE commands to be run at initialization.

Clause 17. The method of any of clauses 11-16, wherein the code to generate the battery information payload according to the battery information payload format comprises one or more of: a battery monitor command configuration file containing information about a configuration of the battery module; or cell balancing command fragments that can be instantiated at run time via parameter data from a cell balancing message received via the radio.

Clause 18. A method of battery diagnostics, comprising: obtaining at least a portion of a container file including metadata defining a battery information payload format and a script for generating a battery information payload from a battery module, via a radio; receiving, from the battery module via the radio, a battery information payload; and parsing the battery information payload according to the battery information payload format to determine measurement information or fault information.

Clause 19. The method of clause 18, wherein obtaining the container file comprises: initializing the battery module; and reading a container file from a non-volatile memory of a radio of the battery module.

Clause 20. The method of clause 18 or 19, wherein obtaining the container file comprises requesting the container file from a wireless battery management system; and receiving the container file from the battery module via the wireless battery management system.

By way of example, an element, or any portion of an element, or any combination of elements may be implemented with a “processing system” that includes one or more processors. Examples of processors include microprocessors, microcontrollers, digital signal processors (DSPs), field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software shall be construed broadly to mean instructions, instruction sets, code, code segments, program code, programs, subprograms, scripts, software modules, applications, software applications, software packages, routines, subroutines, objects, executables, threads of execution, procedures, functions, etc., whether referred to as software, firmware, middleware, microcode, hardware description language, or otherwise.

Accordingly, in one or more aspects, one or more of the functions described may be implemented in hardware, software, firmware, or any combination thereof. If implemented in software, the functions may be stored on or encoded as one or more instructions or code on a computer-readable medium. Computer-readable media includes computer storage media. Storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Disk and disc, as used herein, includes compact disc (CD), laser disc, optical disc, digital versatile disc (DVD), and floppy disk where disks usually reproduce data magnetically, while discs reproduce data optically with lasers. Combinations of the above should also be included within the scope of computer-readable media. Non-transitory computer-readable media excludes transitory signals.

1. A battery module, comprising:
a plurality of battery cells;
a battery monitoring system configured to monitor one or more parameters of the plurality of battery cells;
a processor configured to execute a battery monitoring script to generate a battery information payload defined by a battery information payload format; and
a radio configured to:
receive a container file including metadata defining the battery information payload format and the battery monitoring script;
transmit the metadata to a service device; and
transmit the battery information payload to the service device.

2. The battery module of claim 1, wherein the radio comprises a non-volatile memory configured to store the container file and the processor comprises a volatile memory and is configured to load the battery monitoring script upon initialization.

3. The battery module of claim 1, wherein the radio is configured to transmit the metadata to a wireless battery management system that is configured to provide the metadata to the service device.

4. The battery module of claim 1, wherein the radio is configured to transmit the metadata directly to the service device in response to a request from the service device.

5. The battery module of claim 1, wherein the processor is configured to execute a data processing engine (DPE) to process data received from the battery monitoring system, wherein the battery monitoring script comprises:
a set of battery monitor command source files used to write commands to the battery monitoring system and read results from the battery monitoring system via a serial peripheral interface (SPI); and
a set of DPE source files that provide commands to process the data received from the battery monitoring system to generate the battery information payload according to the battery information payload format.

6. The battery module of claim 5, wherein the processor is configured to execute a scheduler to generate a plurality of packets according to the battery information payload format, wherein the battery monitoring script includes:
an initialization schedule that provides a set of pointers to lists of BMS and DPE commands to be run at initialization; and
an active mode schedule that provides the processor with pointers to lists of battery management system and DPE commands to be run within a timed subloop.

7. The battery module of claim 1, wherein the battery monitoring script includes a battery monitor command configuration file containing information about a configuration of the battery module.

8. The battery module of claim 1, wherein the battery monitoring script includes cell balancing command fragments that can be instantiated at run time via parameter data from a cell balancing message received via the radio.

9. A battery pack comprising:
a plurality of the battery modules according to claim 1; and
a wireless battery management system controller configured to:
receive the battery information payload from each of the plurality of the battery modules; and
provide aggregated battery information to a battery management controller of a host.

10. An electric vehicle comprising the battery pack of claim 9.

11. A method of battery management, comprising:
obtaining, at a processor of a battery module, a container file including metadata defining a battery information payload format and code for generating a battery information payload;
executing the code to generate the battery information payload according to the battery information payload format;
exporting the metadata of the container file, via a radio, to a service device; and
transmitting the battery information payload to the service device via the radio.

12. The method of claim 11, wherein obtaining the container file comprises:
receiving, at the radio, the container file from a wireless battery management system; and
loading the container file from a non-volatile memory of the radio to a volatile memory of the processor.

13. The method of claim 12, wherein exporting the metadata comprises exporting the metadata via the wireless battery management system.

14. The method of claim 11, wherein exporting the metadata comprises transmitting the metadata directly to the service device.

15. The method of claim 11, wherein the code to generate the battery information payload according to the battery information payload format comprises one or more of:
a set of battery monitor commands source files used to write commands and read results to a battery monitoring system via a serial peripheral interface (SPI) from the processor; or
a set of data processing engine (DPE) source files that provide commands to a DPE running on the processor used to process data received from the battery monitoring system.

16. The method of claim 11, wherein the code to generate the battery information payload according to the battery information payload format comprises one or more of:
an active mode schedule that provides the processor with pointers to lists of battery management system (BMS) and DPE commands to be run within a timed subloop; or
an initialization schedule that provides a set of pointers to lists of BMS and DPE commands to be run at initialization.

17. The method of claim 11, wherein the code to generate the battery information payload according to the battery information payload format comprises one or more of:
a battery monitor command configuration file containing information about a configuration of the battery module; or
cell balancing command fragments that can be instantiated at run time via parameter data from a cell balancing message received via the radio.

18. A method of battery diagnostics, comprising:
obtaining at least a portion of a container file including metadata defining a battery information payload format and a script for generating a battery information payload from a battery module, via a radio;
receiving, from the battery module via the radio, a battery information payload; and
parsing the battery information payload according to the battery information payload format to determine measurement information or fault information.

19. The method of claim 18, wherein obtaining the container file comprises:
initializing the battery module; and
reading a container file from a non-volatile memory of a radio of the battery module.

20. The method of claim 18, wherein obtaining the container file comprises:
requesting the container file from a wireless battery management system; and
receiving the container file from the battery module via the wireless battery management system.
